(19) United States
(12) Patent Application Publication
(10) Pub. No.: US 2024/0032279 A1
(43) Pub. Date: Jan. 25, 2024

(54) SEMICONDUCTOR STRUCTURE AND METHOD FOR FABRICATING SAME

(71) Applicant: CHANGXIN MEMORY TECHNOLOGIES, INC., Hefei (CN)

(72) Inventors: YU-CHENG LIAO, Hefei (CN); JOONSUK MOON, Hefei (CN); SEMYEONG JANG, Hefei (CN)

(21) Appl. No.: 18/150,775

(22) Filed: Jan. 5, 2023

(30) Foreign Application Priority Data
Jul. 22, 2022 (CN) 202210872125.8

(51) Int. Cl. H10B 12/00

(52) U.S. Cl. CPC H10B 12/34; H10B 12/053

(57) ABSTRACT

Embodiments provide a semiconductor structure and a fabricating method. The semiconductor structure includes: a gate dielectric layer, a metal gate, a hybrid gate, and an isolation layer. A gate trench and a source/drain region positioned on two sides of the gate trench are formed in the base substrate, and the gate dielectric layer covers a bottom wall and a side wall of the gate trench. A top surface of the metal gate is lower than a bottom surface of the source/drain region, and the metal gate includes a conductive layer and a barrier layer positioned between the conductive layer and the gate dielectric layer. The conductive layer is filled in the gate trench, and the conductive layer covers a surface of the barrier layer. The hybrid gate is stacked on the metal gate, and a top surface of the hybrid gate is lower than a surface of the base substrate.

### CROSSREFERENCE TO RELATED APPLICATION

This application claims priority to Chinese Patent Application No. 202210872125.8, titled “SEMICONDUCTOR STRUCTURE AND METHOD FOR FABRICATING SAME” and filed to the State Patent Intellectual Property Office on Jul. 22, 2022, the entire contents of which are incorporated herein by reference.

### TECHNICAL FIELD

Embodiments of the present disclosure relate to the field of semiconductors, and more particularly, to a semiconductor structure and a method for fabricating the same.

### BACKGROUND

A metal oxide semiconductor (MOS) transistor is an important component in fabrication of integrated circuits. Generally, the MOS transistor is formed on a substrate. The MOS transistor includes a gate electrode, a source region and a drain region are formed in the substrate on two sides of the gate electrode by means of implantation, and a current flowing between the source region and the drain region is controlled by controlling a voltage applied to the gate electrode.

The MOS transistor may be configured to form a memory, and is used, for example, as an access transistor in a dynamic random access memory (DRAM). In the access transistor, the gate electrode is connected to a wordline, the source region is connected to a bitline, and the drain region is connected to a storage capacitor, which is generally configured to store charges representing stored information.

At present, with miniaturization of dimensions of memory cells in a semiconductor memory such as the DRAM, the access transistor of the DRAM generally adopts a buried wordline (BW). However, due to adoption of the BW, not only a gate resistance becomes higher and higher, but also it is easier to generate a gate-induced drain leakage (GIDL) current. That is, when a voltage is applied to the drain region, reverse bias of a PN junction of the drain region may be caused, such that extra hole-electron pairs generated by electric heat energy are driven by an electric field before recombination, which results in electric leakage.

### SUMMARY

Embodiments of the present disclosure provide a semiconductor structure and a method for fabricating the same.

According to some embodiments of the present disclosure, one aspect of the embodiments of the present disclosure provides a semiconductor structure, which includes: a base substrate, a gate dielectric layer, a metal gate, a hybrid gate, and an isolation layer. A gate trench and a source/drain region positioned on two sides of the gate trench are formed in the base substrate. The gate dielectric layer covers a bottom wall and a side wall of the gate trench, and a top surface of the metal gate is lower than a bottom surface of the source/drain region. The metal gate includes a conductive layer and a barrier layer positioned between the conductive layer and the gate dielectric layer, where the conductive layer is filled in the gate trench, and the conductive layer covers a surface of the barrier layer. The hybrid gate is stacked on the metal gate, and a top surface of the hybrid gate is lower than a surface of the base substrate. The hybrid gate includes a doped conductive layer, where a material of the doped conductive layer includes a mixture of a germanium-silicon material and polysilicon. The isolation layer is stacked on the hybrid gate, and the isolation layer fills up the gate trench.

According to some embodiments of the present disclosure, another aspect of the embodiments of the present disclosure further provides a method for fabricating a semiconductor structure. The method includes: providing a base substrate, where a gate trench is formed in the base substrate, and a source/drain region is respectively formed on two sides of the gate trench; forming a gate dielectric layer and a metal gate in sequence in the gate trench; forming a hybrid gate on the metal gate, where a top surface of the hybrid gate is lower than a surface of the base substrate, and a material of the hybrid gate includes a mixture of a germanium-silicon material and polysilicon; and forming an isolation layer on the hybrid gate, where the isolation layer fills up the gate trench.

### BRIEF DESCRIPTION OF THE DRAWINGS

Exemplary descriptions of one or more embodiments are made by means of pictures in corresponding drawings, and these exemplary descriptions do not constitute a limitation on the embodiments. Unless otherwise stated, the pictures in the drawings do not constitute a scale limitation. Exemplary descriptions are made to one or more embodiments with reference to pictures in the corresponding drawings, and these exemplary descriptions do not constitute limitations on the embodiments. Unless otherwise stated, the figures in the accompanying drawings do not constitute a scale limitation. To describe the technical solutions of the embodiments of the present disclosure or those of the prior art more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic cross-sectional structural diagram of a semiconductor structure according to an embodiment of the present disclosure;

FIGS. 2 to 5 are multiple schematic cross-sectional structural diagrams of a semiconductor structure according to another embodiment of the present disclosure;

FIG. 6 is a schematic flow diagram of a method for fabricating a semiconductor structure according to one embodiment of the present disclosure; and

FIGS. 7 to 20 are schematic cross-sectional structural diagrams of a semiconductor structure corresponding to each step of a method for fabricating the semiconductor structure according to an embodiment of the present disclosure.

### DETAILED DESCRIPTION

As can be known from the background art, an existing buried wordline (BW) not only causes a gate resistance to become higher and higher, but also makes it easier to generate a gate-induced drain leakage (GIDL) current, which adversely affects performance of a semiconductor structure.

To reduce the GIDL current, the semiconductor structure is generally fabricated by alternately etching gate materials (such as tungsten and titanium nitride) to form an Ω shape. The semiconductor structure includes a gate dielectric layer and a base substrate where a gate trench is formed, where the gate dielectric layer is formed along an inner surface of the gate trench. A first gate layer and a second gate layer are sequentially stacked on a surface of the gate dielectric layer. An isolation layer covers the first gate layer and the second gate layer and fills up the gate trench.

Generally, a source/drain region is also formed on two sides of the gate trench in the semiconductor structure to serve as a source and a drain of the semiconductor structure. To reduce the GIDL current during the operation of the semiconductor structure, the Ω shape is generally formed on an upper surface of the second gate layer and an upper surface of the first gate layer by means of an alternate etching method. However, it is relatively difficult to form such an Ω shape, for example, it is relatively difficult to control a height difference between the upper surface of the second gate layer and the upper surface of the first gate layer. In addition, the first gate layer and the second gate layer are generally formed of a homogeneous conductive material, respectively. In an operating state, an electric field formed between the first gate layer and a channel region of the semiconductor structure is relatively uniform. In a region where the source/drain region and the first gate layer overlap vertically (i.e., an overlapping range of the source/drain region and the first gate layer in a depth direction of the gate trench), an injection barrier of charges injected into the channel region of the semiconductor structure from the source/drain region is relatively large, such that a start-up voltage of a transistor is relatively large, resulting in slower turn-on speed of the transistor.

To reduce fabrication difficulty of the transistor, reduce the GIDL current and improve the turn-on speed of the transistor, an embodiment of the present disclosure provides a semiconductor structure, which includes a base substrate, a gate dielectric layer, a metal gate, a hybrid gate, and an isolation layer. A gate trench and a source/drain region positioned on two sides of the gate trench are formed in the base substrate. The gate dielectric layer covers a bottom wall and a side wall of the gate trench, and a top surface of the metal gate is lower than a bottom surface of the source/drain region. The metal gate includes a conductive layer, which is filled in the gate trench. The hybrid gate is stacked on the metal gate, and a top surface of the hybrid gate is lower than a surface of the base substrate. The hybrid gate includes a doped conductive layer, where a material of the doped conductive layer includes a mixture of a germanium-silicon material and polysilicon. The isolation layer is stacked on the hybrid gate, and the isolation layer fills up the gate trench. In the embodiments of the present disclosure, the gate dielectric layer, the metal gate and the hybrid gate are provided in the gate trench, where the hybrid gate includes the doped conductive layer, and the material of the doped conductive layer includes the mixture of the germanium-silicon material and polysilicon. In this way, the resistance of the doped conductive layer may be reduced without reducing a drive voltage of the semiconductor structure, thereby reducing a partial voltage of the doped conductive layer to reduce the electric field between the hybrid gate and the drain, and reducing the GIDL current caused by a strong electric field, and thus improving refresh performance of the semiconductor structure.

The embodiments of the present disclosure will be described in detail below in conjunction with the accompanying drawings. However, a person of ordinary skill in the art may understand that in the embodiments of the present disclosure, many technical details are put forward such that a reader may better understand the embodiments of the present disclosure. However, the technical solutions requested to be protected by the embodiments of the present disclosure may also be implemented even without these technical details or various variations and modifications based on the following embodiments.

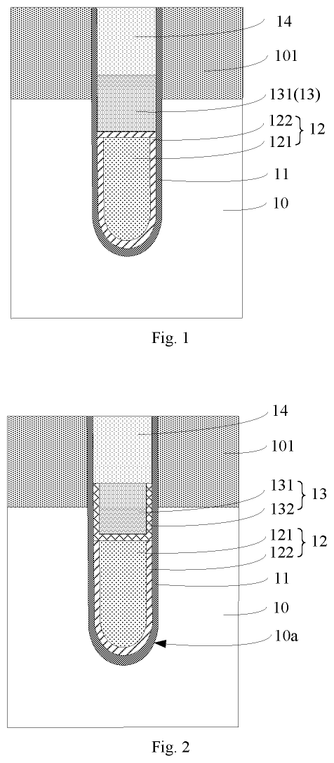

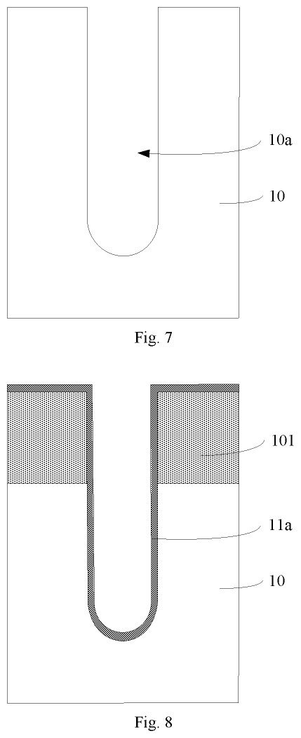

One embodiment of the present disclosure provides a semiconductor structure, which will be described in detail below with reference to the accompanying drawings. FIGS. 1 to 5 are schematic diagrams of the semiconductor structure according to the embodiment of the present disclosure. FIG. 6 is a schematic flow diagram of a method for fabricating a semiconductor structure according to the embodiment of the present disclosure. It should be noted that, for the ease of description and clear illustration of the steps of the method for fabricating the semiconductor structure, FIGS. 7 to 20 in this embodiment are schematic diagrams showing partial structures of the semiconductor structure.

The semiconductor structure provided by the embodiment of the present disclosure will be described in more detail below with reference to the accompanying drawings.

Referring to FIG. 1, an embodiment of the present disclosure provides a semiconductor structure, which includes a base substrate 10, a gate dielectric layer 11, a metal gate 12, a hybrid gate 13, and an isolation layer 14. A gate trench 10a and a source/drain region positioned on two sides of the gate trench 10a are formed in the base substrate 10. The gate dielectric layer 11 covers a bottom wall and a side wall of the gate trench 10a, and a top surface of the metal gate 12 is lower than a bottom surface of the source/drain region. The metal gate 12 includes a conductive layer 121 and a barrier layer 122 positioned between the conductive layer 121 and the gate dielectric layer 11, where the conductive layer 121 is filled in the gate trench 10a, and the conductive layer 121 covers a surface of the barrier layer 122. The hybrid gate 13 is stacked on the metal gate 12, and a top surface of the hybrid gate 13 is lower than a surface of the base substrate 10. The hybrid gate 13 includes a doped conductive layer 131, where a material of the doped conductive layer 131 includes a mixture of a germanium-silicon material and polysilicon. The isolation layer 14 is stacked on the hybrid gate 13, and the isolation layer 14 fills up the gate trench 10a.

In the above semiconductor structure, the doped conductive layer 131 may be, for example, an N-type doped conductive layer, which can better reduce the resistance and reduce RC delay. The doped conductive layer 131 may be formed into a mixed layer of N-type doped silicon-germanium and polysilicon by means of deposition. Moreover, the mixed layer of N-type doped silicon-germanium and polysilicon has the same thermal stability and similar work function as N-type doped polysilicon, which meets gate performance requirements under miniaturization of dimensions of memory cells in the DRAM. In the embodiments of the present disclosure, the gate dielectric layer 11, the metal gate 12, the hybrid gate 13, and the isolation layer 14 jointly constitute the BW, an extension direction of the BW is the same as that of the gate trench 10a, and a flow direction of a current in the wordline is the same as the extension direction of the gate trench 10a. In addition, a vertical distance between the top surface of the hybrid gate 13 and the top surface of the base substrate 10 should be greater than a preset distance, to prevent the hybrid gate 13 from overlapping with the source/drain region 101 on two sides of the base substrate 10 in a horizontal direction.

It should be noted that, as shown in FIG. 1, when the doped conductive layer 131 made of the mixture of germanium-silicon material and polysilicon is used as the hybrid gate 13, the conductive layer 121 of the metal gate 12 positioned under the hybrid gate 13 covers the surface of the barrier layer 122, and the barrier layer 122 covers the top surface of the conductive layer 121. That is, the barrier layer 122 completely wraps the conductive layer 121, the cross section of the barrier layer 122 is an enclosed U-shaped structure, and the conductive layer 121 is filled in the gate trench 10a surrounded by the barrier layer 122. Herein, the barrier layer 122 mainly plays a role of adhesion and barrier. The barrier layer 122 completely wraps the conductive layer 121, which increases a wrapping area of the barrier layer 122 to the conductive layer 121. Therefore, the adhesion of the material between the barrier layer 122 and the conductive layer 121 is increased. Meanwhile, the barrier layer 122 covers the top surface of the conductive layer 121, and plays a good role of separation and barrier between the doped conductive layer 131 and the conductive layer 121, which is convenient for adjusting the overall performance of the gate structure, thereby improving the overall performance of the semiconductor structure.

Referring to FIG. 2, another embodiment of the present disclosure provides a semiconductor structure, and the hybrid gate 13 of the semiconductor structure further includes: a work function layer 132 positioned between the doped conductive layer 131 and the gate dielectric layer 11, where the doped conductive layer 131 covers a surface of the work function layer 132, and the work function layer 132 is configured to separate the doped conductive layer 121 from the metal gate 12. The work function layer 132 can improve a work function of the gate.

With continued reference to FIG. 2, in some embodiments, a cross section of the work function layer 132 is U-shaped along an extension direction of the gate trench 10a. The doped conductive layer 131 is positioned in a region enclosed by the work function layer 132, and the doped conductive layer 131 covers an inner wall of the work function layer 132. The work function layer 132 not only separates the gate dielectric layer 11 from the doped conductive layer 131, but also separates the doped conductive layer 131 from the conductive layer 121.

In some embodiments, a material of the work function layer 132 includes silicon carbide or doped silicon carbide. A material of the doped conductive layer 131 may be a mixture of a silicon-germanium material and polysilicon. The hybrid gate formed by the silicon-germanium material and polysilicon of the doped conductive layer 131 and silicon carbide of the work function layer 132 further reduces the gate resistance, reduces the RC delay, and improves the work function of the gate. A band gap Φ of N-type doped silicon carbide (SiC) is 3.1 eV, and the band gap Φ of N-type doped silicon is 4.17 eV. The band gap of N-type doped SiC combined with polysilicon is significantly lower than that of N-type doped polysilicon, which may effectively reduce the GIDL caused by a leakage current between bands. In addition, meanwhile, the doped conductive layer 131 is a mixed layer of N-type doped silicon-germanium and polysilicon, which has the same thermal stability and similar work function as N-type doped polysilicon, and meets the gate performance requirements under miniaturization of the dimensions of the memory cells in the DRAM.

It should be noted that, when the hybrid gate 13 includes the work function layer 132 and the doped conductive layer 131, referring to FIG. 2, the structure of the barrier layer 122 in the metal gate 12 positioned under the hybrid gate 13 is different from that of the barrier layer 122 in FIG. 1. In the semiconductor structure shown in FIG. 2, the barrier layer 122 in the metal gate 12 is an open U-shaped structure, and the bottom surface of the work function layer 132 covers the top surface of the conductive layer 121, to have a barrier effect on the doped conductive layer 131 and the conductive layer 121 positioned under the doped conductive layer 131.

In the embodiments of the present disclosure, as shown in FIG. 2, the metal gate 12 is filled in the groove surrounded by the gate dielectric layer 11, the barrier layer 122 covers the bottom surface and part of the side wall of the gate dielectric layer 11, the conductive layer 121 covers the surface of the barrier layer 122, and the top surface of the conductive layer 121 is flush with or lower than the top surface of the barrier layer 122. The barrier layer 122 mainly plays the role of adhesion and barrier, not only for adhering to the gate dielectric layer 11 and the conductive layer 121, but also for preventing metal ions in the conductive layer 121 from migrating into the gate dielectric layer 11 and the base substrate 10.

It should be noted that, because the hybrid gate 13 also needs to be stacked on the metal gate 12, the vertical distance between the top surface of the metal gate 12 and the top surface of the base substrate 10 in the direction perpendicular to the surface of the base substrate 10 should be greater than a maximum doping depth of the source/drain region, to ensure that a positional relationship between the hybrid gate formed subsequently and the source/drain region meets the performance requirements of the BW.

In some embodiments, a material of the conductive layer 121 includes tungsten, and a material of the barrier layer 122 includes titanium nitride.

In some embodiments, the material of the barrier layer 122 is different from the material of the work function layer 132. That is, the barrier layer 122 and the work function layer 132 are two individuals independent of each other. For example, the material of the barrier layer 122 is titanium nitride, and the material of the work function layer 132 is silicon carbide doped with N-type ions.

In some embodiments, the work function of the material of the barrier layer 122 may be greater than the work function of the material of the work function layer 132. When the work function of the material of the barrier layer 122 is greater than that of the material of the work function layer 132, the conductive layer 121 is less sensitive to electrons in the channel, and it is relatively difficult to induce occurrence of a leakage current in the channel, so the channel can accommodate more electrons. Correspondingly, the work function of the material of the work function layer 132 may be set to be smaller, such that the doped conductive layer 131 can more easily drive the electrons in a gate-drain overlapping region to move to the channel, thereby reducing the electrons in the gate-drain overlapping region and the electric field in the gate-drain overlapping region, and suppressing the GIDL current in the gate-drain overlapping region. Moreover, because the electrons are more easily driven to move toward the channel, the movement of the electrons can be effectively controlled without applying a greater drive voltage.

In some embodiments, the top surface of the doped conductive layer 131 is flush with or lower than the top surface of the work function layer 132. In some embodiments, referring to FIG. 2, the top surface of the doped conductive layer 131 is flush with the top surface of the work function layer 132.

In some embodiments, the top surface of the conductive layer 121 is flush with or lower than the top surface of the barrier layer 122. In some embodiments, with continued reference to FIG. 2, the top surface of the conductive layer 121 is flush with the top surface of the barrier layer 122.

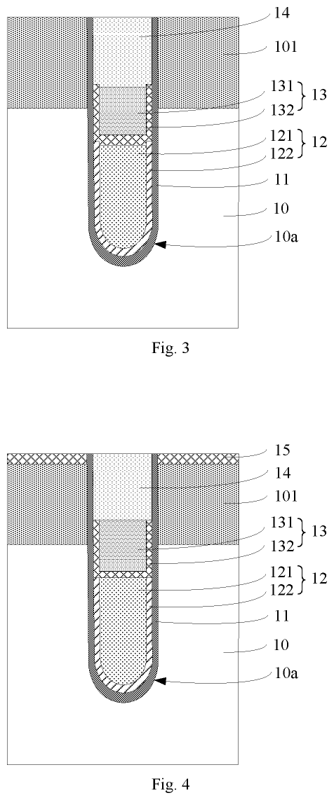

Of course, it is to be understood that, referring to FIG. 3, the top surface of the doped conductive layer 131 may also be lower than the top surface of the work function layer 132. As shown in FIG. 3, the top surface of the doped conductive layer 131 is slightly lower than the top surface of the work function layer 132. Similarly, the top surface of the conductive layer 121 may also be slightly lower than the top surface of the barrier layer 122.

Referring to FIG. 4, in some embodiments, the above-mentioned semiconductor structure further includes: a buffer layer 15 positioned on the surface of the source/drain region.

In some embodiments, a material of the buffer layer 15 includes silicon carbide (SiC); and/or the buffer layer 15 is doped with dopant ions therein.

In some embodiments, the dopant ions include titanium ions. In the embodiments of the present disclosure, silicon carbide doped with the titanium ions (SiC+Ti) may be used as a contact buffer layer, which provides a good ohmic contact to connection between the source/drain region 101 and the bitline.

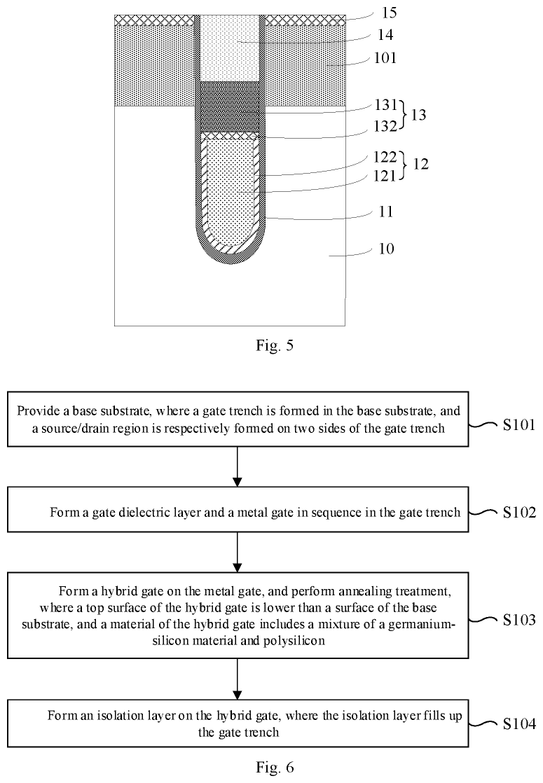

In some other embodiments, referring to FIG. 5, the work function layer 132 may also only cover the top surface of the metal gate 12, to expose the side wall of the gate dielectric layer 11 positioned above the metal gate 12, such that the doped conductive layer 131 formed above the work function layer 132 covers the surface of the work function layer 132 and part of the side wall of the gate dielectric layer 11. The doped conductive layer 131 and the conductive layer 121 are spaced by means of the work function layer 132, and the work function layer 132 covers the surface of the metal gate 12, to have a barrier effect on the doped conductive layer 131 and the conductive layer 121, thereby preventing the metal ions in the doped conductive layer 131 from migrating into the conductive layer 121.

In the embodiments of the present disclosure, the gate dielectric layer 11 includes a first portion covered by the metal gate 12 and a second portion covered by the hybrid gate 13, where the second portion is positioned above the first portion. In the horizontal direction perpendicular to the extension direction of the gate channel 10a and parallel to the surface of the base substrate 10, a width of the second portion is equal to that of the first portion. In this way, it is ensured that space is reserved for the metal gate 12 and the hybrid gate 13, and it is ensured that the doped conductive layer 131 and the hybrid gate 13 using the doped conductive layer 131 as a conductive body have good conductive properties.

Correspondingly, an embodiment of the present disclosure further provides a method for fabricating a semiconductor structure, which may be configured for forming the semiconductor structure in the above-mentioned embodiments. Referring to FIG. 6, the method for fabricating the semiconductor structure provided by the embodiment of the present disclosure includes following steps.

Step S101: providing a base substrate, where a gate trench is formed in the base substrate, and a source/drain region is respectively formed on two sides of the gate trench.

Step S102: forming a gate dielectric layer and a metal gate in sequence in the gate trench.

Step S103: forming a hybrid gate on the metal gate, and performing annealing treatment, where a top surface of the hybrid gate is lower than a surface of the base substrate, and a material of the hybrid gate comprises a mixture of a germanium-silicon material and polysilicon.

Step S104: forming an isolation layer on the hybrid gate, where the isolation layer fills up the gate trench.

The method for fabricating the semiconductor structure provided by the embodiment of the present disclosure will be described in detail below with reference to the accompanying drawings.

Referring to FIG. 7, a base substrate 10 is provided, a gate trench 10a is formed in the base substrate 10, and a source/drain region 101 is formed on two sides of the gate trench 10a.

In some embodiments, a material of the base substrate 10 may be silicon, germanium, silicon germanium or silicon carbide, etc., or may be silicon on insulator (SOI) or germanium on insulator (GOI), or may be other materials, for example, Group III or Group V compounds such as gallium arsenide. The base substrate 10 may also be implanted with certain dopant particles according to design requirements to change electrical parameters.

FIG. 7 shows the base substrate 10 where the gate trench 10a is formed according to one embodiment of the present disclosure. The base substrate 10 may be patterned by etching for one or multiple times to form the gate trench 10a.

Before the gate trench 10a is filled and a buried gate (including the metal gate 12 and the hybrid gate 13) of the semiconductor structure is formed, as shown in FIG. 8, the source/drain region 101 is formed on two sides of the gate trench 10a, respectively. The top surface of the metal gate 12 fabricated subsequently needs to be lower than the bottom surface of the source/drain region 101. The source/drain region 101 extends from the two sides of the gate trench 10a to the surface of the base substrate 10. The two source/drain regions 101 on the two sides of the gate trench 10a may be used as the source and the drain of the transistor, respectively. The source/drain region 101 may be formed by implanting an N-type or P-type dopant into the base substrate 10 on the two sides of the gate trench 10a.

As an example, before the gate trench 10a is formed, a pad oxide layer and a hard mask layer may be deposited first on the surface of the base substrate 10, a layer of photoresist is then spin-coated on the upper surface of the hard mask layer, and a mask is configured to perform an exposure and development process to open the photoresist in the region of the gate trench 10a. Next, the photoresist with an opening pattern is configured to etch downward as a mask. The etching method is, for example, plasma dry etching. The hard mask layer and the pad oxide layer in the region of the gate trench 10a are etched with openings, and then the base substrate 10 is etched by using the hard mask layer and the pad oxide layer with the opening pattern as the mask, to form the gate trench 10a in the base substrate 10. The material of the pad oxide layer is, for example, silicon oxide, and the material of the hard mask layer is, for example, silicon nitride. The method for forming the hard mask layer and the pad oxide layer is, for example, chemical vapor deposition (CVD) or physical vapor deposition (PVD) and other deposition methods, but is not limited thereto. For the convenience of illustration, the drawings in the embodiments of the present disclosure do not illustrate the pad oxide layer and the hard mask layer.

In the embodiments of the present disclosure, the gate trench 10a may be configured to form the gate of the transistor therein, and correspondingly, the source/drain region of the transistor may be formed in the base substrate 10 in the side wall of the gate trench 10a. In addition, a trench used as a shallow trench isolation (STI) structure may also be formed in the base substrate 10. For clarity, FIG. 7 shows only one gate trench 10a configured to form the gate of the transistor. The depth of the gate trench 10a ranges from about 100 nm to 400 nm.

Referring to FIG. 8, a gate dielectric film 11a is formed in the gate trench 10a, and the gate dielectric film 11a conformally covers the bottom wall and side wall of the gate trench 10a and the surface of the base substrate 10. Herein, “conformal coverage” refers to conformal deposition along the covered surface, and may also be referred to as conformal coverage.

In some embodiments, the gate dielectric film 11a may include a silicon dioxide layer with a thickness of 50 Å to 150 Å. The gate dielectric film 11a may be formed by means of, for example, an oxidation process such as wet or dry thermal oxidation in an environment including oxide, water vapor, nitric oxide, or a combination thereof, or an in-situ steam generation (ISSG) process in an environment including oxide, water vapor, nitric oxide, or a combination thereof, or a chemical vapor deposition (CVD) technology using tetraethyl orthosilicate (TEOS) and oxygen as precursors. In some embodiments, the gate dielectric film 11a may also include a high-k dielectric material.

It should be noted that, before the gate dielectric film 11a is formed, the channel region in the base substrate 10 may be formed by means of implantation along the inner surface of the gate trench 10a, and the type of implanted ions may be selected according to the type of the transistor to be formed.

Referring to FIG. 9, the gate dielectric film 11a is etched to expose the surface of the base substrate 10 to form the gate dielectric layer 11, and a barrier material film 122a covering the side wall of the gate trench 10a is formed on the surface of the gate dielectric layer 11. The top surface of the gate dielectric layer 11 is flush with the surface of the base substrate 10, the barrier material film 122a covers the surface of the gate dielectric layer 11, and the barrier material film 122a covers the surface of the base substrate 10.

In the embodiments of the present disclosure, the etching process is a wet etching process. In this way, it is advantageous to uniformly etching the exposed gate dielectric layer 11, such that in the direction perpendicular to the surface of the base substrate 10, the widths of the gate dielectric layers 11 at different positions are equal or tend to be equal, which ensures that the gate dielectric layer 11 has stable performance and better isolation effect. Moreover, it is advantageous to avoiding causing ion bombardment damage to the top surface of the metal gate 12, and to ensuring that a smaller contact resistance is provided between the metal gate 12 and the hybrid gate 13 formed subsequently.

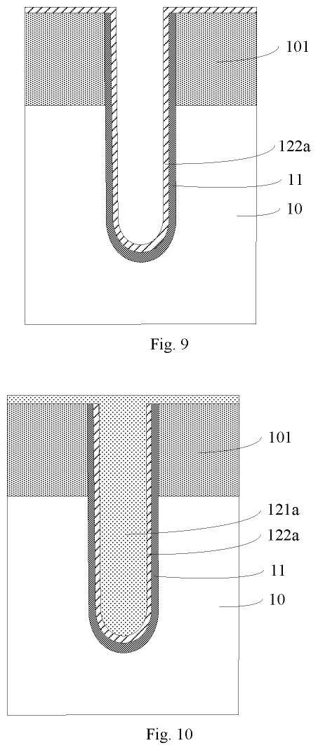

Next, referring to FIG. 10, after the barrier material film 122a is deposited on the surface of the gate dielectric layer 11, the barrier material film 122a is then anisotropically etched, and a remaining part of the barrier material film 122a covers the side surface of the gate dielectric layer 11 and the bottom surface of the gate dielectric layer 11. Next, a conductive film 121a is deposited on the surface of the barrier material film 122a, where the conductive film 121a covers the surface of the barrier material film 122a and the surface of the base substrate 10, and the conductive film 121a fills up the gate trench 10a.

In some embodiments, a material of the conductive film 121a includes a metal such as tantalum, titanium, molybdenum, tungsten, platinum, aluminum, hafnium, or ruthenium. In the embodiments of the present disclosure, the material of the conductive film 121a is tungsten.

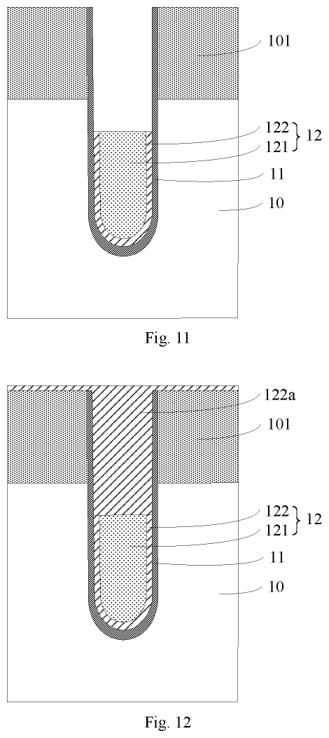

Next, referring to FIG. 11, the conductive film 121a and the barrier material film 122a are etched back to form a conductive layer 121 and a barrier layer 122. The conductive layer 121 covers a surface of the barrier layer 122, and the barrier layer 122 is positioned between the conductive layer 121 and the gate dielectric layer 11. By selecting a suitable etch-back process, upper surfaces of the barrier layer 122 and of the conductive layer 121 in the gate trench 10a may be substantially flush. Viewed from a depth direction of the gate trench 10a, a height of the conductive layer 121 ranges from about 40 nm to 130 nm.

In the embodiments of the present disclosure, the etch-back process is a wet etching process, such that it is advantageous to avoiding causing ion bombardment damage to the surface of the conductive layer 121, and to ensuring that a smaller contact resistance is provided between the conductive layer 121 and the doped conductive layer 131 formed subsequently.

As shown in FIG. 11, the top of the conductive layer 121 is exposed to the barrier layer 122. To improve barrier quality and adhesion quality of the barrier layer 122, referring to FIG. 12, the barrier material film 122a is deposited on the top surface of the conductive layer 121 and the top surface of the barrier layer 122, the barrier material film 122a is filled in the gate trench 10a, and the barrier material film 122a covers the surface of the gate dielectric layer 11 and the surface of the base substrate 10.

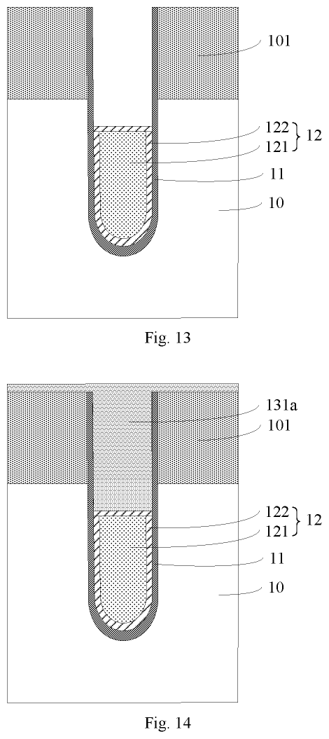

Next, referring to FIG. 13, the barrier material film 122a is etched back to form the metal gate 12, and the top surface of the metal gate 12 is lower than the bottom surface of the source/drain region 101. In this case, the barrier layer 122 is an enclosed U-shaped structure, and the conductive layer 121 is positioned within the region surrounded by the barrier layer 122. The barrier layer 122 completely wraps the conductive layer 121, which improves the adhesion between the conductive layer and the barrier layer 122. Moreover, the metal gate 12 and the hybrid gate 13 formed subsequently are spaced by the barrier layer 122, to prevent metal ions in the doped conductive layer 131 formed subsequently from migrating into the conductive layer 121. Therefore, the barrier layer 122 having the enclosed U-shaped structure can also have a good barrier effect.

In some embodiments, the material of the barrier layer 122 and the material of the conductive layer 121 include metals (e.g., tantalum, titanium, molybdenum, tungsten, platinum, aluminum, hafnium, and ruthenium), metal silicides (e.g., titanium silicide, cobalt silicide, nickel silicide, and tantalum silicide), metal nitrides (e.g., titanium nitride and tantalum nitride), polysilicon-doped conductive materials, materials in other conductive materials, or combinations thereof. The barrier layer 122 includes a conductive material with a higher work function. In the embodiments of the present disclosure, the barrier layer 122 includes, for example, a titanium nitride layer with a thickness ranging from 10 Å to 50 Å, and the work function of titanium nitride (TiN) is about 4.7 eV. The material of the conductive layer 121 includes, for example, tungsten.

In the embodiments of the present disclosure, the gate dielectric layer 11, the barrier layer 122, and the conductive layer 121 stacked in sequence are formed along the bottom wall of the gate trench 10a, and the barrier layer 122 is made of a conductive material with a higher work function, to facilitate reducing the leakage current of the channel region of the transistor positioned under the bottom wall of the gate trench 10a.

Next, the hybrid gate 13 is formed above the metal gate 12.

Referring to FIG. 14, the doped conductive film 131a filling up the gate trench 10a is formed on the surface of the gate dielectric layer 11, and the doped conductive film 131a covers the surface of the base substrate 10.

In some embodiments, the material of the doped conductive film 131a includes a polysilicon-doped conductive material or a combination with other conductive materials. For example, the material of the doped conductive film 131a may be a mixture of a silicon-germanium material and polysilicon.

Next, annealing treatment is performed on the doped conductive film 131a. For example, the doped conductive film 131a is annealed by means of laser, such that amorphous silicon in the doped conductive film 131a is recrystallized to have a more uniform ion concentration and crystallinity. Because an effective resistance of the gate in the semiconductor device is related to the concentration uniformity of the dopant ions in the crystalline silicon gate and the penetration degree of the dopant ions, the doped conductive layer 131 may be obtained by means of laser annealing treatment, to obtain polysilicon with high penetration degree for the dopant ions. In addition, a relatively more uniform doping concentration may be obtained after P-type or N-type ions are doped in the polysilicon, thereby improving the concentration uniformity of the dopant ions in the hybrid gate of the final semiconductor device and the penetration degree of the dopant ions, reducing the gate resistance, and thus improving the performance of the semiconductor structure.

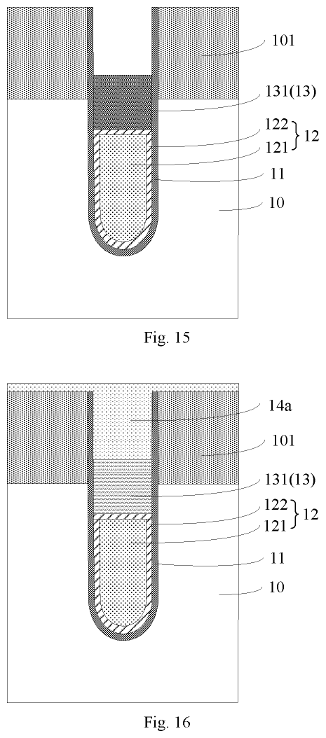

Referring to FIG. 15, the doped conductive film 131a is etched back to form the hybrid gate 13, where the top surface of the hybrid gate 13 is lower than the surface of the base substrate 10, and the bottom surface of the hybrid gate 13 covers the top surface of the barrier layer 122. When the hybrid gate 13 includes the doped conductive layer 131, the doped conductive film 131a is deposited on the top surface of the barrier layer 122, and then the doped conductive film 131a is etched back to form the doped conductive layer 131.

In some embodiments, the doped conductive film 131a is etched by means of the etch-back process, to remove the doped conductive film 131a on the surface of the base substrate 10 and part of the doped conductive film 131a positioned in the gate trench 10a, and a certain height of the doped conductive film 131a is retained to form the doped conductive layer 131, where the top surface of the doped conductive layer 131 is lower than that of the gate dielectric layer 11. With continued reference to FIG. 15, the source/drain region 101 is positioned on the two sides of the gate trench 10a of the base substrate 10, where the top surface of the doped conductive layer 131 is lower than that of the source/drain region 101, and the bottom surface of the doped conductive layer 131 is lower than that of the source/drain region 101.

Referring to FIG. 16, the isolation film 14a is deposited in the gate trench 10a, the isolation film 14a fills up the gate trench 10a, and the isolation film 14a covers the side wall of the gate dielectric layer 11 and the surface of the base substrate 10. Next, a planarization process is performed on the isolation film 14a, the isolation film 14a on the surface of the base substrate 10 is removed, and the isolation film 14a filling up the gate trench 10a is retained as the isolation layer 14 to form the semiconductor structure as shown in FIG. 1. As shown in FIG. 1, the surface of the isolation layer 14 is flush with the surface of the gate dielectric layer 11 and the surface of the base substrate 10. It should be noted that, because the source/drain region 101 may be formed by implanting N-type or P-type dopants into the base substrate 10 on the two sides of the gate trench 10a, prior to the ion implantation, part of the isolation film 14a on the surface of the base substrate 10 may be removed by means of, for example, a chemical mechanical polishing (CMP) process.

In the above embodiments of the present disclosure, the hybrid gate 13 includes the doped conductive layer 131, and the metal gate 12 includes the barrier layer 122 and the conductive layer 121 completely wrapped by the barrier layer 122, where the barrier layer has the enclosed U-shaped structure, and the barrier layer 122 covers the top surface of the conductive layer 121 and can have a good barrier effect, to prevent the metal ions in the doped conductive layer 131 positioned above the conductive layer 121 from migrating into the conductive layer 121. Moreover, because the barrier layer 122 completely wraps the conductive layer 121, a contact area between the barrier layer 122 and the conductive layer 121 is larger, which can also play a good adhesion role.

In another embodiment of the present disclosure, the hybrid gate 13 further includes the work function layer 132 configured to space the doped conductive layer 131 from the gate dielectric layer 11. After the gate dielectric layer 11 and the metal gate 12 are sequentially formed in the gate trench 10a, that is, after the conductive layer 121 and the barrier layer 122 of the open U-shaped structure are formed, the hybrid gate 13 is formed above the metal gate 12 including the barrier layer 22 and the conductive layer 121.

In some embodiments, the process step of forming the hybrid gate 13 include: forming, on the metal gate 12, a work function film 132a covering a side wall of the gate trench 10a and a top surface of the metal gate 12; forming, on a surface of the work function film 132a, a doped conductive film 131a filling up the gate trench 10a; and etching back the work function film 132a and the doped conductive film 131a to form the hybrid gate 13, where the top surface of the hybrid gate 13 is lower than the surface of the base substrate 10.

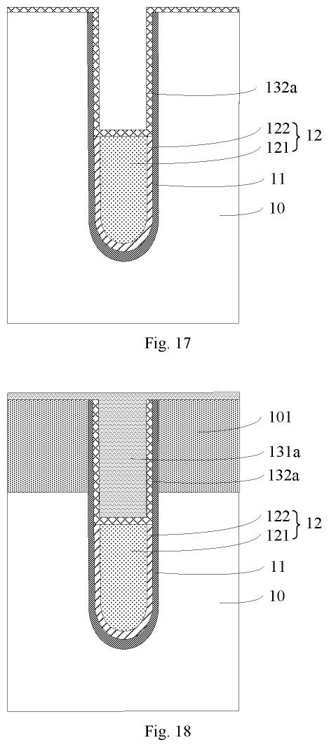

In some other embodiments, the metal gate 12 of the semiconductor structure includes the doped conductive layer 131 and the work function layer 132. When the metal gate 12 includes the doped conductive layer 131 and the work function layer 132, referring to FIG. 17, after the metal gate 12 is formed, the work function film 132a is formed on the surface of the conductive layer 121 and the surface of the barrier layer 122, and the work function film 132a covers the exposed side wall of the gate dielectric layer 11, the top surface of the conductive layer 121 and the surface of the base substrate 10. Next, the work function film 132a is anisotropically etched, and a remaining part of the work function film 132a covers the side surface of the gate dielectric layer 11 and the top surface of the metal gate 12. Next, referring to FIG. 18, the doped conductive film 131a is deposited in the gate trench 10a, and the doped conductive film 131a fills up the gate trench 10a and covers the surface of the base substrate 10. The doped conductive layer 131 is formed by etching back the doped conductive film 131a. The material of the doped conductive layer 131 includes, for example, a mixture of a silicon-germanium material and polysilicon.

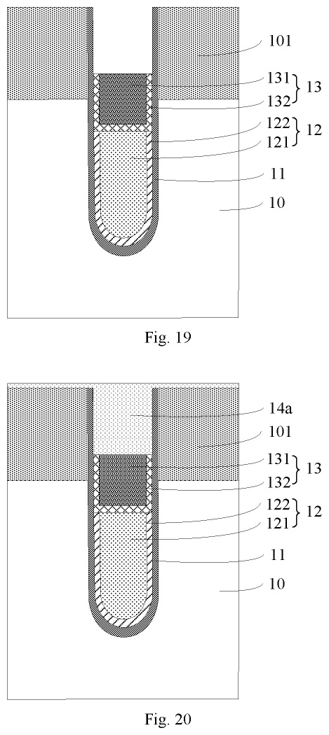

Referring to FIG. 19, the work function layer 132 and the doped conductive layer 131 are formed by etching back the work function film 132a and the doped conductive film 131a. The work function layer 132 is positioned between the doped conductive layer 131 and the gate dielectric layer 11, the doped conductive layer 131 covers the surface of the work function layer 132, and the doped conductive layer 131 and the metal gate 12 are spaced by means of the work function layer 132. The gate dielectric layer 11 and the doped conductive layer 131 are spaced by means of the work function layer 132, and the doped conductive layer 131 covers the conductive layer 121 and fills between the gate trenches 10a. By selecting a suitable etch-back process, the upper surface of the work function layer 132 and the upper surface of the doped conductive layer 131 in the gate trench 10a are substantially flush. In the depth direction of the gate trench 10a, the height of the doped conductive layer 131 ranges from about 10 nm to 50 nm.

In some embodiments, after forming the hybrid gate 13 and before forming the isolation layer 14, the method further includes: performing annealing treatment. In some embodiments, after the doped conductive film 131a is deposited and before the isolation film 14a is deposited, the doped conductive film 131a is annealed to make the ion concentration and crystallinity of the doped conductive layer 131 formed more uniform, thereby reducing the resistance of the hybrid gate 13, and effectively suppressing the GIDL current. The annealing process may use laser annealing.

In the embodiments of the present disclosure, as shown in FIG. 19, the work function layer 132 and the doped conductive layer 131 do not fill up the gate trench 10a. Furthermore, referring to FIG. 20, the isolation film 14a is formed in the gate trench 10a above the hybrid gate 13, and the isolation film 14a covers the surface of the hybrid gate 13 and the surface of the base substrate and fills up the gate trench 10a. In some embodiments, the isolation film 14a may be deposited on the top surface of the work function layer 132 and the top surface of the doped conductive layer 131 by means of, for example, the CVD process, and the isolation film 14a fills up the gate trench 10a. The isolation film 14 may include silicon nitride, silicon oxide, silicon oxynitride, other insulating materials, or a combination thereof.

Next, the isolation film 14a on the surface of the base substrate 10 is removed by means of the etch-back process, and the isolation film 14a covering the hybrid gate 13 is retained to form the isolation layer 14 to obtain the semiconductor structure as shown in FIG. 2, where the top surface of the isolation layer 14 is flush with the surface of the base substrate 10.

In the embodiments of the present disclosure, to not affect the function of the semiconductor device, as shown in FIG. 2, the hybrid gate 13 spatially overlaps with at least part of the source/drain region 101 in the depth direction of the gate trench 10a.

In some embodiments, before forming the gate dielectric layer 11 in the gate trench 10a, the method further includes: forming a buffer layer 15 on a surface of the source/drain region 101 positioned on the two sides of the gate trench 10a; and performing doping treatment on the buffer layer 15.

Referring to FIG. 4, the buffer layer 15 is formed on the surface of the source/drain region 101. In the embodiments of the present disclosure, a material of the buffer layer 15 is silicon carbide, and the buffer layer 15 is doped with dopant ions, which are titanium ions. Silicon carbide doped with the titanium ions (SiC+Ti) may be used as the buffer layer 15, to provide a good ohmic contact to connection between the source/drain region 101 and the bitline.

In the semiconductor structure provided in the embodiments of the present disclosure, the gate dielectric layer 11, the metal gate 12 and the hybrid gate 13 are provided in the gate trench 10a. The hybrid gate 13 includes a doped conductive layer 131, a material of the doped conductive layer 131 includes a mixture of a germanium-silicon material and polysilicon, and the doped conductive layer 131 is annealed for recrystallization to obtain germanium-silicon polysilicon having high penetration degree to the dopant ions, thereby increasing concentration uniformity and penetration degree of the dopant ions in the hybrid gate 13 of the semiconductor device, reducing gate resistance to reduce an electric field between the hybrid gate 13 and the drain, such that the GIDL current caused by a strong electric field is reduced, and thus refresh performance of the semiconductor structure can be improved. The above semiconductor structure may be fabricated by means of the method for fabricating the semiconductor structure provided in the embodiments of the present disclosure, and no strict process control is required to form the surface (e.g., an Ω shape) of a gate material so the fabrication difficulty is relatively low.

The semiconductor structure provided in the embodiments of the present disclosure may be used for an integrated circuit memory, such as a DRAM array. The DRAM array has a plurality of memory cells, and the access transistors of some or all of the memory cells may have the characteristics of the above semiconductor structure. The DRAM array may form a metal interconnection structure above the gate trench and a wordline positioned in the metal interconnection structure, and the metal gate and the hybrid gate may be connected to the wordline. The DRAM array may also include a bitline positioned in the metal interconnection structure and a bitline contact for electrically connecting the bitline to one of the source/drain regions of the semiconductor structure below. Other one of the source/drain regions of the semiconductor structure is electrically connected to a storage node by means of a storage node contact, where the storage node is, for example, a metal insulator metal capacitor, a planar capacitor, a U-shaped capacitor, a vertical capacitor, a horizontal capacitor, or a non-capacitor storage structure, etc.

Those of ordinary skill in the art can understand that the above-mentioned embodiments are some embodiments for realizing the present disclosure, but in practical applications, various changes may be made to them in form and details without departing from the spirit and scope of the present disclosure. Any person skilled in the art can make their own changes and modifications without departing from the spirit and scope of the present disclosure. Therefore, the protection scope of the present disclosure shall be subject to the scope defined by the claims.

What is claimed is:

1. A semiconductor structure, comprising:
a base substrate, wherein a gate trench and a source/drain region positioned on two sides of the gate trench are formed in the base substrate;
a gate dielectric layer covering a bottom wall and a side wall of the gate trench;
a metal gate, a top surface of the metal gate being lower than a bottom surface of the source/drain region, the metal gate comprising a conductive layer and a barrier layer positioned between the conductive layer and the gate dielectric layer, wherein the conductive layer is filled in the gate trench, and the conductive layer covers a surface of the barrier layer;
a hybrid gate stacked on the metal gate, a top surface of the hybrid gate being lower than a surface of the base substrate, and the hybrid gate comprising a doped conductive layer, wherein a material of the doped conductive layer comprises a mixture of a germanium-silicon material and polysilicon; and
an isolation layer stacked on the hybrid gate, the isolation layer filling up the gate trench.

2. The semiconductor structure according to claim 1, wherein the hybrid gate further comprises a work function layer positioned between the doped conductive layer and the gate dielectric layer;
wherein the doped conductive layer covers a surface of the work function layer, and the work function layer is configured to separate the doped conductive layer from the metal gate.

3. The semiconductor structure according to claim 2, wherein a cross section of the work function layer is U-shaped along an extension direction of the gate trench.

4. The semiconductor structure according to claim 2, wherein a top surface of the doped conductive layer is flush with or lower than a top surface of the work function layer.

5. The semiconductor structure according to claim 2, wherein a material of the work function layer comprises silicon carbide or doped silicon carbide.

6. The semiconductor structure according to claim 1, wherein a top surface of the conductive layer is flush with or lower than a top surface of the barrier layer.

7. The semiconductor structure according to claim 1, further comprising: a buffer layer positioned on a surface of the source/drain region.

8. The semiconductor structure according to claim 7, wherein a material of the buffer layer comprises silicon carbide; and/or the buffer layer is doped with a dopant ion therein.

9. The semiconductor structure according to claim 8, wherein the dopant ion comprises a titanium ion.

10. A method for fabricating a semiconductor structure, comprising:
providing a base substrate, wherein a gate trench is formed in the base substrate, and a source/drain region is respectively formed on two sides of the gate trench;
forming a gate dielectric layer and a metal gate in sequence in the gate trench;
forming a hybrid gate on the metal gate, wherein a top surface of the hybrid gate is lower than a surface of the base substrate, and a material of the hybrid gate comprises a mixture of a germanium-silicon material and polysilicon; and
forming an isolation layer on the hybrid gate, wherein the isolation layer fills up the gate trench.

11. The method for fabricating the semiconductor structure according to claim 10, wherein the forming the hybrid gate comprises:
forming, on the metal gate, a work function film covering a side wall of the gate trench and a top surface of the metal gate;
forming, on a surface of the work function film, a doped conductive film filling up the gate trench; and
etching back the work function film and the doped conductive film to form the hybrid gate, wherein the top surface of the hybrid gate is lower than the surface of the base substrate.

12. The method for fabricating the semiconductor structure according to claim 10, wherein the forming the metal gate comprises:
forming, on the gate dielectric layer, a barrier material film covering the side wall of the gate trench;
forming, on a surface of the barrier material film, a conductive film filling up the gate trench; and
etching back the barrier material film and the conductive film to form the metal gate, wherein the top surface of the metal gate is lower than a bottom surface of the source/drain region.

13. The method for fabricating the semiconductor structure according to claim 10, wherein before forming the gate dielectric layer in the gate trench, the method further comprises:
forming a buffer layer on a surface of the source/drain region positioned on the two sides of the gate trench; and
performing doping treatment on the buffer layer.

14. The method for fabricating the semiconductor structure according to claim 10, wherein after forming the hybrid gate and before forming the isolation layer, the method further comprises: performing annealing treatment.
